(19) United States
(12) Patent Application Publication
(10) Pub. No.: US 2024/0318985 A1
(43) Pub. Date: Sep. 26, 2024

(54) GRIP SENSOR AND ELECTRONIC DEVICE WITH OFFSET DRIFT REMOVAL FUNCTION DUE TO TEMPERATURE

(71) Applicant: SAMSUNG ELECTRO-MECHANICS CO., LTD., Suwon-si (KR)

(72) Inventors: Joo Yul KO, Suwon-si (KR); Joo Hyoung LEE, Suwon-si (KR)

(73) Assignee: SAMSUNG ELECTRO-MECHANICS CO., LTD., Suwon-si (KR)

(21) Appl. No.: 18/422,418

(22) Filed: Jan. 25, 2024

(30) Foreign Application Priority Data
Mar. 23, 2023 (KR) 10-2023-0037789

(51) Int. Cl. G01D 5/24; G04F 10/00

(52) U.S. Cl. CPC G01D 5/24; G04F 10/005

(57) ABSTRACT

A grip sensor includes a first sensing member and a second sensing member, disposed on different positions in a case of an electronic device to sense proximity of a human body; a first sensing oscillator configured to generate a first oscillation signal when connected to the first sensing member; a second sensing oscillator configured to generate a second oscillation signal when connected to the second sensing member; a time-to-digital converter configured to set the second oscillation signal as a first reference signal, when a first switch is in an on-state, and generate a first sensing signal using the first oscillation signal and the first reference signal; and a digital processor configured to sense the proximity of the human body to the first sensing member, using the first sensing signal.

### CROSS-REFERENCE TO RELATED APPLICATIONS

This application claims the benefit under 35 USC 119(a) of Korean Patent Application No. 10-2023-0037789 filed on Mar. 23, 2023, in the Korean Intellectual Property Office, the entire disclosure of which is incorporated herein by reference for all purposes.

### 1. FIELD

The present disclosure relates to a grip sensor and an electronic device having an offset drift removal function due to temperature.

### 2. DESCRIPTION OF THE BACKGROUND

In general, a grip sensor may be a sensor for controlling electromagnetic waves of a mobile phone based on the proximity of a human body. The grip sensor may mainly use an optical sensor method or a capacitive sensor method. The optical sensor method was mainly used in the past, but there were disadvantages, such as a large application area, a high price, and a large amount of power consumption due to light source usage.

Due to the disadvantages of the optical sensor method, the capacitive sensor method is increasingly being adopted as the grip sensor.

An existing grip sensor in which the capacitive sensor method is adopted may include a capacitance/voltage (C/V) converter converting capacitance (C), which changes due to grip (e.g., the approach of a human body), into voltage (V) to detect the grip, and an analog/digital (A/D) converter converting an analog signal to a digital signal.

The existing grip sensor includes the C/V converter and the A/D converter, and a change in ambient temperature affects an internal reference voltage, an amplifier circuit characteristic, a resistance value, and a change in capacitance in the C/V converter and the A/D converter. Accordingly, there may be problems in that an external temperature distorts the sensing value of the grip sensor.

For example, when the C/V converter and the A/D converter included in the existing grip sensor use an element or a circuit sensitive to a change in temperature, there is a problem that an internal circuit output or input value may be changed to ultimately reduce the resolution thereof.

The above information is presented as background information only to assist with an understanding of the present disclosure. No determination has been made, and no assertion is made, as to whether any of the above might be applicable as prior art with regard to the disclosure.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a grip sensor includes a first sensing member and a second sensing member, disposed on different positions in a case of an electronic device to sense proximity of a human body; a first sensing oscillator configured to generate a first oscillation signal having a first frequency, varying based on proximity of the human body, when connected to the first sensing member, and having a preset reference frequency, when not connected to the first sensing member; a second sensing oscillator configured to generate a second oscillation signal having a second frequency, varying based on the proximity of the human body, when connected to the second sensing member, and having the preset reference frequency, when not connected to the second sensing member; a first switch configured connect or disconnect from the first sensing member and the first sensing oscillator; a second switch configured to operate complementarily to the first switch, and connect or disconnect from the second sensing member and the second sensing oscillator; a time-to-digital converter configured to set the second oscillation signal as a first reference signal, when the first switch is in an on-state, and generate a first sensing signal using the first oscillation signal and the first reference signal; and a digital processor configured to sense the proximity of the human body to the first sensing member, using the first sensing signal.

The time-to-digital converter may be configured to set the first oscillation signal as a second reference signal, when the second switch is in an on-state, and generate a second sensing signal using the second reference signal and the second oscillation signal. The digital processor may be configured to sense the proximity of the human body to the second sensing member, using the second sensing signal.

The grip sensor may further include a controller is configured to generate a first control signal, a second control signal, a third control signal, and a fourth control signal. The time-to-digital converter may include a first time-to-digital converter synchronized with an operation of the first switch according to the third control signal, generating a first reference signal using the second oscillation signal when the first switch is in an on-state, and generating a first sensing signal using the first oscillation signal and the first reference signal; and a second time-to-digital converter synchronized with an operation of the second switch according to the fourth control signal, generating a second reference signal using the first oscillation signal, when the second switch is in an on-state, and generating a second sensing signal using the second reference signal and the second oscillation signal.

The first control signal may have a high level signal and a low level signal, periodically repeated, and become a high level signal at a first time to and be output the first switch. The second control signal may have a high level signal at a second time when the first control signal has a low level signal, and is output to the second switch. The third control signal may have an enable level signal synchronized at a first time of the first control signal and is output to a first time-digital converter. The fourth control signal may have an enable level signal synchronized at a second time of the second control signal and is output to a second time-digital converter. In response to the first control signal, the first switch may be in an on-state at a first time to connect the first sensing member and the first sensing oscillator, and may be in an off-state at the second time to disconnect the first sensing member and the first sensing oscillator. In response to the second control signal, the second switch may be in an on-state at a second time to connect the second sensing member and the second sensing oscillator, and may be in an off-state at the first time to disconnect the second sensing member and the second sensing oscillator. In response to the third control signal having an enable level signal at a first time and a disable level signal at a second time, the first time-to-digital converter may perform an operation at the first time and stop an operation at the second time. In response to the fourth control signal having a disable level signal at a first time and an enable level signal at a second time, the second time-to-digital converter may perform an operation at the second time and stop an operation at the first time.

The first time-to-digital converter may include a first frequency down converter configured to lower a frequency of the second oscillation signal, when the first switch is in an on-state, to generate the first reference signal; and a first time-to-digital converter (TDC) circuit unit synchronized with an operation of the first switch according to the third control signal, and configured to count the first oscillation signal using the first reference signal, when the first switch is in an on-state, to generate the first sensing signal. The second time-to-digital converter may include a second frequency down converter configured to lower a frequency of the first oscillation signal to generate the second reference signal; and a second TDC circuit unit synchronized with an operation of the second switch according to the fourth control signal, and configured to count the second oscillation signal using the second reference signal, when the second switch is in an on-state, to generate the second sensing signal.

The time-to-digital converter may include a first multiplexer configured to select one of the first oscillation signal or the second oscillation signal according to a third control signal, and output a first selection signal; a second multiplexer configured to select the other one of the first oscillation signal or the second oscillation signal according to a fourth control signal, and output a second selection signal; a frequency down converter configured to lower a frequency of the second selection signal from the second multiplexer to output a reference signal; a TDC circuit unit configured to count the first selection signal from the first multiplexer using the reference signal from the frequency down converter, to generate a sensing signal; and a demultiplexer synchronized with an operation of the first multiplexer according to a fifth control signal, and configured to output the sensing signal from the TDC circuit unit to one of a first output terminal or a second output terminal.

The grip sensor may further include a controller configured to have a high level signal and a low level signal, periodically repeated, generating and outputting a first control signal having a high level signal at a first time to the first switch, generating and outputting a second control signal having a high level signal at a second time to the second switch when the first control signal has a low level signal, generating and outputting a third control signal synchronized at a first time of the first control signal to the first multiplexer, generating and outputting a fourth control signal synchronized at a second time of the second control signal to the second multiplexer, and generating and outputting a fifth control signal synchronized with the first control signal to the demultiplexer.

In response to the first control signal, the first switch may be in an on-state at a first time to connect the first sensing member and the first sensing oscillator, and in an off-state at the second time to disconnect the first sensing member and the first sensing oscillator. In response to the second control signal, the second switch may be in an on-state at a second time to connect the second sensing member and the second sensing oscillator, and in an off-state at the first time to disconnect the second sensing member and the second sensing oscillator. In response to the third control signal having a first time, a high level signal, and a second time, a low level signal, the first multiplexer may be configured to select the first oscillation signal at the first time and select the second oscillation signal at the second time. In response to the fourth control signal having a first time, a disable level signal, and a second time, an enable level signal, the second multiplexer may be configured to select the second oscillation signal at the second time and select the first oscillation signal at the first time. In response to the fifth control signal having a first time, a high level signal, and a second time, a low level signal, the demultiplexer may output the sensing signal output from the TDC circuit unit at the first time according to the fifth control signal, a high level signal, through a first output terminal, and output the sensing signal output from the TDC circuit unit at the second time according to the fifth control signal, a low level signal, through a second output terminal.

In another general aspect, an electronic device includes a case of the electronic device; a grip sensor disposed in the case to sense proximity of a human body; and an electronic device circuit configured to receive a detection signal from the grip sensor. The grip sensor includes: a first sensing member and a second sensing member, disposed on different positions in the case to sense the proximity of the human body; a first sensing oscillator configured to generate a first oscillation signal having a first frequency, varying based on the proximity of the human body, when connected to the first sensing member, and having a preset reference frequency, when not connected to the first sensing member; a second sensing oscillator configured to generate a second oscillation signal having a second frequency, varying based on the proximity of the human body, when connected to the second sensing member, and having the reference frequency, when not connected to the second sensing member; a first switch configured to connect or disconnect from the first sensing member and the first sensing oscillator; a second switch configured to operate complementarily to the first switch, and connect or disconnect from the second sensing member and the second sensing oscillator; a time-to-digital converter configured to set the second oscillation signal as a first reference signal, when the first switch is in an on-state, and generate a first sensing signal using the first oscillation signal and the first reference signal; and a digital processor configured to sense the proximity of the human body to the first sensing member, using the first sensing signal.

The time-to-digital converter may be configured to set the first oscillation signal as a second reference signal, when the second switch is in an on-state, and generate a second sensing signal using the second reference signal and the second oscillation signal. The digital processor may be configured to sense the proximity of the human body to the second sensing member, using the second sensing signal.

The electronic device may further include a controller configured to generate a first control signal, a second control signal, a third control signal, and a fourth control signal. The time-to-digital converter may include a first time-to-digital converter synchronized with an operation of the first switch according to the third control signal, generating a first reference signal using the second oscillation signal, when the first switch is in an on-state, and generating a first sensing signal using the first oscillation signal and the first reference signal; and a second time-to-digital converter synchronized with an operation of the second switch according to the fourth control signal, generating a second reference signal using the first oscillation signal, when the second switch is in an on-state, and generating a second sensing signal using the second reference signal and the second oscillation signal.

The first control signal may have a high level signal and a low level signal, periodically repeated, and become a high level signal at a first time to and be output the first switch SW1. The second control signal may have a high level signal at a second time when the first control signal has a low level signal, and output to the second switch. The third control signal may have an enable level signal synchronized at a first time of the first control signal and output to a first time-digital converter. The fourth control signal may have an enable level signal synchronized at a second time of the second control signal and output to a second time-digital converter.

In response to the first control signal, the first switch may be in an on-state at a first time to connect the first sensing member and the first sensing oscillator, and in an off-state at the second time to disconnect the first sensing member and the first sensing oscillator. In response to the second control signal, the second switch may be in an on-state at a second time to connect the second sensing member and the second sensing oscillator, and in an off-state at the first time to disconnect the second sensing member and the second sensing oscillator. In response to the third control signal having an enable level signal at a first time and a disable level signal at a second time, the first time-to-digital converter may perform an operation at the first time and stop an operation at the second time. In response to the fourth control signal having a disable level signal at a first time and an enable level signal at a second time, the second time-to-digital converter may perform an operation at the second time and stop an operation at the first time.

The first time-to-digital converter may include a first frequency down converter configured to lower a frequency of the second oscillation signal to generate the first reference signal; and a first time-to-digital converter (TDC) circuit unit synchronized with an operation of the first switch according to the third control signal, and configured to count the first oscillation signal using the first reference signal, when the first switch is in an on-state, to generate the first sensing signal. The second time-to-digital converter may include a second frequency down converter configured to lower a frequency of the first oscillation signal to generate the second reference signal; and a second TDC circuit unit synchronized with an operation of the second switch according to the fourth control signal, and configured to count the second oscillation signal using the second reference signal, when the second switch is in an on-state, to generate the second sensing signal.

The time-to-digital converter may include a first multiplexer configured to select one of the first oscillation signal or the second oscillation signal according to a third control signal, and output a first selection signal; a second multiplexer configured to select the other one of the first oscillation signal or the second oscillation signal according to a fourth control signal, and output a second selection signal; a frequency down converter configured to lower a frequency of the second selection signal from the second multiplexer to output a reference signal; a TDC circuit unit configured to count the first selection signal from the first multiplexer using the reference signal from the frequency down converter, to generate a sensing signal; and a demultiplexer synchronized with an operation of the first multiplexer according to a fifth control signal, and configured to output the sensing signal from the TDC circuit unit to one of a first output terminal or a second output terminal.

The electronic device may further include a controller configured to have a high level signal and a low level signal, periodically repeated, generating and outputting a first control signal having a high level signal at a first time to the first switch, generating and outputting a second control signal having a high level signal at a second time to the second switch when the first control signal has a low level signal, generating and outputting a third control signal synchronized at a first time of the first control signal to the first multiplexer, generating and outputting a fourth control signal synchronized at a second time of the second control signal to the second multiplexer, and generating and outputting a fifth control signal synchronized with the first control signal to the demultiplexer.

In response to the first control signal, the first switch may be in an on-state at a first time to connect the first sensing member and the first sensing oscillator, and in an off-state at the second time to disconnect the first sensing member and the first sensing oscillator. In response to the second control signal, the second switch may be in an on-state at a second time to connect the second sensing member and the second sensing oscillator, and in an off-state at the first time to disconnect the second sensing member and the second sensing oscillator. In response to the third control signal having a first time, a high level signal, and a second time, a low level signal, the first multiplexer may be configured to select the first oscillation signal at the first time and select the second oscillation signal at the second time. In response to the fourth control signal having a first time, a disable level signal, and a second time, an enable level signal, the second multiplexer may be configured to select the second oscillation signal at the second time and select the first oscillation signal at the first time. In response to the fifth control signal having a first time, a high level signal, and a second time, a low level signal, the demultiplexer may output the sensing signal output from the TDC circuit unit at the first time according to the fifth control signal, a high level signal, through a first output terminal, and output the sensing signal output from the TDC circuit unit at the second time according to the fifth control signal, a low level signal, through a second output terminal.

Other features and aspects will be apparent from the following detailed description, the drawings, and the claims.

### BRIEF DESCRIPTION OF DRAWINGS

FIG. 1 is a block diagram illustrating a grip sensor according to an embodiment of the present disclosure.

FIG. 2 is a block diagram illustrating a grip sensor according to an embodiment of the present disclosure.

FIG. 3 is a block diagram illustrating an electronic device having a grip sensor according to an embodiment of the present disclosure.

FIG. 4 is a view illustrating a time-digital converter.

FIG. 5 is another view illustrating a time-digital converter.

FIG. 6 is a view illustrating a first control signal and a second control signal.

FIG. 7 is a view illustrating first and second control signals and first and second oscillation signals.

FIG. 8 is a view illustrating an operation of a first time-to-digital converter using a first oscillation signal and a first reference signal.

FIG. 9 is a view illustrating an operation of a second time-to-digital converter using a second oscillation signal and a second reference signal.

FIG. 10 is a view illustrating a change in count ratio, respectively, for a first oscillation signal (for sensor signal) of a first sensing oscillator and a second oscillation signal (for reference signal) of a second sensing oscillator according to a change in temperature.

FIG. 11 is a view illustrating an application of a grip sensor according to the present disclosure to an electronic device.

Throughout the drawings and the detailed description, unless otherwise described, the same reference numerals refer to the same elements. The drawings may not be to scale, and the relative size, proportions, and depiction of elements in the drawings may be exaggerated for clarity, illustration, and convenience.

### DETAILED DESCRIPTION

Hereinafter, while examples of the present disclosure will be described in detail with reference to the accompanying drawings, it is noted that examples are not limited to the same.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of this disclosure. For example, the sequences of operations described herein are merely examples, and are not limited to those set forth herein, but may be changed as will be apparent after an understanding of this disclosure, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of this disclosure.

Throughout the specification, when an element, such as a layer, region, or substrate is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items; likewise, “at least one of” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms, such as “above,” “upper,” “below,” “lower,” and the like, may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above,” or “upper” relative to another element would then be “below,” or “lower” relative to the other element. Thus, the term “above” encompasses both the above and below orientations depending on the spatial orientation of the device. The device may also be oriented in other ways (rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

Herein, it is noted that use of the term “may” with respect to an example, for example, as to what an example may include or implement, means that at least one example exists in which such a feature is included or implemented while all examples are not limited thereto.

The features of the examples described herein may be combined in various ways as will be apparent after an understanding of this disclosure. Further, although the examples described herein have a variety of configurations, other configurations are possible as will be apparent after an understanding of this disclosure.

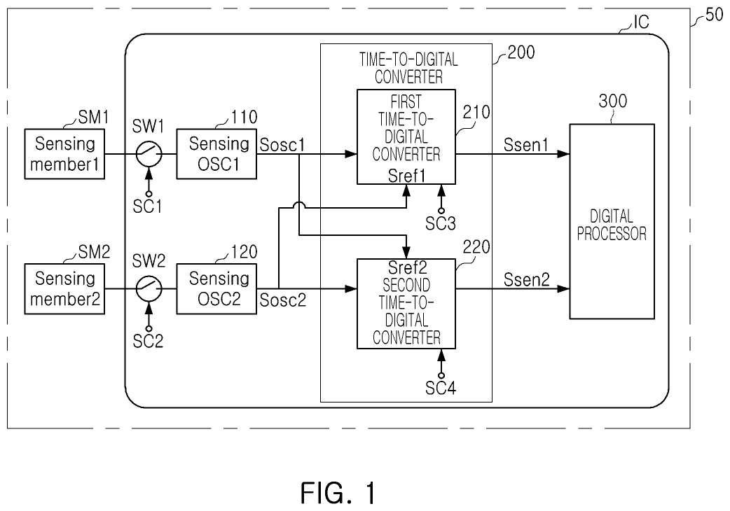

FIG. 1 is a block diagram illustrating a grip sensor according to an embodiment of the present disclosure.

Referring to FIG. 1, a grip sensor 50, according to an embodiment of the present disclosure, may include a first sensing member SM1, a second sensing member SM2, a first sensing oscillator 110, a second sensing oscillator 120, a first switch SW1, a second switch SW2, a time-to-digital converter 200, and a digital processor 300.

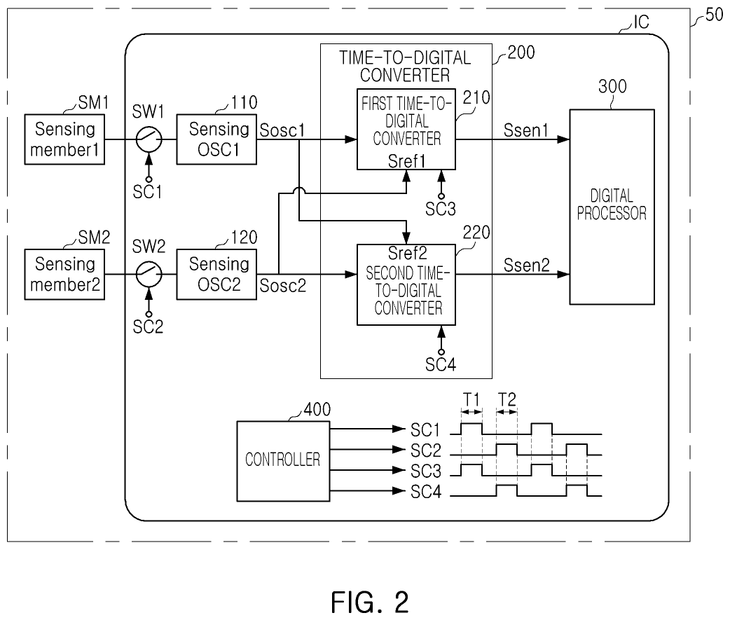

FIG. 2 is a block diagram illustrating a grip sensor according to an embodiment of the present disclosure.

A grip sensor 50 illustrated in FIG. 2 may additionally include a controller 400 to the grip sensor 50 in FIG. 1.

The controller 400 may generate a first control signal (SC1), a second control signal (SC2), a third control signal (SC3), and a fourth control signal (SC4). The first control signal SC1 may have a high level and a low level, periodically repeated, and may become high level at a first time T1 to and be output the first switch SW1. The second control signal SC2 may have a high level at a second time T2 when the first control signal SC1 has a low level, and be output to the second switch SW2. The third control signal SC3 may have an enable level synchronized at a first time T1 of the first control signal SC1 and be output to a first time-digital converter 210. The fourth control signal SC4 may have an enable level synchronized at a second time T2 of the second control signal SC2 and be output to a second time-digital converter 220.

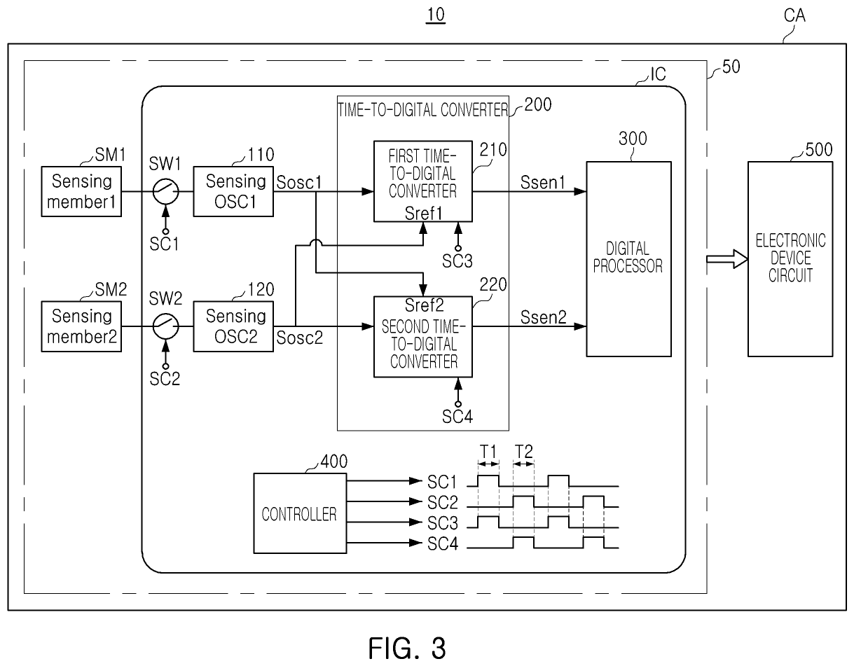

Referring to FIGS. 1 and 2, the first sensing member SM1 may be disposed in a case (CA in FIG. 3) of an electronic device, may sense the approach of a human body, and may provide capacitance changing according to the approach of a human body to the first sensing oscillator 110.

The second sensing member SM2 may be disposed in the case (CA in FIG. 3) of the electronic device at a different position from the first sensing member SM1, and may provide capacitance changing according to the approach of a human body to the second sensing oscillator 120.

In the present disclosure, the first sensing member SM1 and the second sensing member SM2 may be formed as a printed pattern on a substrate such as a printed circuit board (PCB), a flexible printed circuit board (FPCB), or the like, or may be implemented as a wire regardless of the substrate, but are only illustrative, and are not limited thereto.

The first sensing oscillator 110 may generate a first oscillation signal Sosc1 having a first frequency, changing according to the approach of a human body, when connected to the first sensing member SM1, and having a preset reference frequency when not connected to the first sensing member SM1.

For example, the first sensing oscillator 110 may provide a first oscillation signal Sosc1 having a first frequency, changing according to the approach of a human body through the first sensing member SM1, when connected to the first sensing member SM1 by the first switch SW1, which is in an on-state. In addition, the first sensing oscillator 110 may provide a first oscillation signal Sosc1 having a preset reference frequency regardless of the approach or proximity of the human body, when not connected to the first sensing member SM1 by the first switch SW1, which is in an off-state.

The second sensing oscillator 120 may generate a second oscillation signal Sosc2 having a second frequency, changing according to the approach of a human body when connected to the second sensing member SM2, and having the reference frequency when not connected to the second sensing member SM2.

For example, the second sensing oscillator 120 may provide a second oscillation signal Sosc2 having a second frequency, changing according to the approach of a human body through the second sensing member SM2, when connected to the second sensing member SM2 by the second switch SW2, which is in an on-state. In addition, the second sensing oscillator 120 may provide a second oscillation signal Sosc2 having a preset reference frequency regardless of the approach of the human body, when not connected to the second sensing member SM2.

The first switch SW1 may operate in an on-state or an off-state to be connected to or disconnected from the first sensing member SM1 and the first sensing oscillator 110.

For example, the first switch SW1 may connect or disconnect the first sensing oscillator 110 and the first sensing member SM1 according to the first control signal SC1 of the controller 400.

For example, when a voltage level of the first control signal SC1 is a high level (e.g., 1.5V), the first switch SW1 may be in an on-state, and the first sensing oscillator 110 may be connected to the first sensing member SM1 by the first switch SW1. Alternatively, when a voltage level of the first control signal SC1 is a low level (e.g., 0V), the first switch SW1 may be in an off-state, and the first sensing oscillator 110 may be disconnected from the first sensing member SM1 by the first switch SW1. In the present disclosure, although it is illustrated that the switch is set to be controlled in the on-state when the control signal is at a high level, it is also possible to set the switch to be controlled in the on-state when the control signal is at a low level.

The second switch SW2 may operate complementary to the first switch SW1, and may operate in an on-state or an off-state to be connected to or disconnected from the second sensing member SM2 and the second sensing oscillator 120.

For example, the second switch SW2 may or may not be connected to the second sensing oscillator 120 according to the second control signal SC2 of the controller 400. For example, when a voltage level of the second control signal SC2 is a high level (e.g., 1.5V), the second switch SW2 may be in an on-state, and the second sensing oscillator 120 may be connected to the second sensing member SM2 by the second switch SW2. Alternatively, when a voltage level of the second control signal SC2 is a low level (e.g., 0V), the second switch SW2 may be in an off-state, and the second sensing oscillator 120 may be disconnected from the second sensing member SM2 by the second switch SW2.

When the first switch SW1 is in an on-state (the second switch SW2 is in an off-state), the time-to-digital converter 200 may set the second oscillation signal Sosc2 as a first reference signal Sref1, and may generate a first sensing signal Ssen1 using the first oscillation signal Sosc1 and the first reference signal Sref1. When the second switch SW2 is in an on-state (the first switch SW1 is in an off-state), the time-to-digital converter 200 may set the first oscillation signal Sosc1 as a second reference signal Sref2, and may generate a second sensing signal Ssen2 using the second reference signal Sref2 and the second oscillation signal Sosc2.

The digital processor 300 may detect the human body, approaching the first sensing member SM1 and the second sensing member SM2, respectively, using the first sensing signal Ssen1 or the second sensing signal Ssen2 to output a detection signal.

The time-to-digital converter 200 may include a first time-to-digital converter 210 and a second time-to-digital converter 220.

The first time-to-digital converter 210 may be synchronized with an operation of the first switch SW1 according to the third control signal SC3, may generate a first reference signal Sref1 using the second oscillation signal Sosc2, when the first switch SW1 is in an on-state, and may generate a first sensing signal Ssen1 using the first oscillation signal Sosc1 and the first reference signal Sref1.

For example, when the first switch SW1 is in an on-state (the second switch SW2 is in an off-state), the first time-to-digital converter 210 may generate a first reference signal Sref1, enabled according to a third control signal SC3, which is a high level, using the second oscillation signal Sosc2 input from the second sensing oscillator 120 disconnected from the second sensing member SM2, and may generate a first sensing signal Ssen1 using the first reference signal Sref1 and the first oscillation signal Sosc1 input from the first sensing oscillator 110 connected to the first sensing member SM1. In this case, the second time-to-digital converter 220 may be in a disabled state according to a fourth control signal SC4.

The second time-to-digital converter 220 may be synchronized with an operation of the second switch SW2 according to the fourth control signal SC4, may generate a second reference signal Sref2 using the first oscillation signal Sosc1, when the second switch SW2 is in an on-state, and may generate a second sensing signal Ssen2 using the second reference signal Sref2 and the second oscillation signal Sosc2.

For example, when the second switch SW2 is in an on-state (the first switch SW1 is in an off-state), the second time-digital converter 220 may generate a second reference signal Sref2, enabled according to a fourth control signal SC4, which is a high level, using the first oscillation signal Sosc1 input from the first sensing oscillator 110 disconnected from the first sensing member SM1, and may generate a second sensing signal Ssen2 using the second reference signal Sref2 and the second oscillation signal Sosc2 input from the second sensing oscillator 120 connected to the second sensing member SM2. In this case, the first time-to-digital converter 210 may be in a disabled state according to a third control signal SC3.

For each drawing of the present disclosure, redundant descriptions of components with the same symbols and function will be omitted, and possible differences between the drawings may be explained.

In the present disclosure, the first sensing oscillator 110, the second sensing oscillator 120, the first switch SW1, the second switch SW2, the time-to-digital converter 200, and the digital processor 300 may be included to be implemented with at least one integrated circuit IC.

FIG. 3 is a block diagram illustrating an electronic device having a grip sensor according to an embodiment of the present disclosure.

Referring to FIG. 3, an electronic device 10, according to an embodiment of the present disclosure, may include a case CA of the electronic device, the grip sensor 50, and an electronic device circuit 500.

The case CA of the electronic device may be an external case that surrounds at least a portion of the electronic device 10. For example, the case CA may include an antenna, which may be a portion of the case. The antenna, a portion of the case CA, may be segmented and electrically separated from a different portion of the case CA.

The grip sensor 50 may be disposed in the case CA of the electronic device or in the antenna, a portion of the case, and may be a sensor for sensing approach of a human body.

Since this may be replaced with the contents explained with reference to FIGS. 1 and 2, the description of the redundant content will be omitted.

The electronic device circuit 500 may receive a detection signal from the grip sensor 50, and may determine whether the human body approaches each of the first and second sensing members SM1 and SM2.

Referring to FIGS. 1 to 3, in response to the first control signal SC1, the first switch SW1 may be in an on-state at a first time T1 to connect the first sensing member SM1 and the first sensing oscillator 110, and may be in an off-state at the second time T2 to disconnect the first sensing member SM1 and the first sensing oscillator 110.

In response to the second control signal SC2, the second switch SW2 may be in an on-state at a second time T2 to connect the second sensing member SM2 and the second sensing oscillator 120, and may be in an off-state at the first time T1 to disconnect the second sensing member SM2 and the second sensing oscillator 120.

In response to the third control signal SC3 having an enable level at a first time T1 and a disable level at a second time T2, the first time-to-digital converter 210 may perform an operation at the first time T1 and may stop an operation at the second time T2.

In response to the fourth control signal SC4 having a disable level at a first time T1 and an enable level at a second time T2, the second time-to-digital converter (TDC) 220 may perform an operation at the second time T2 and may stop an operation at the first time T1.

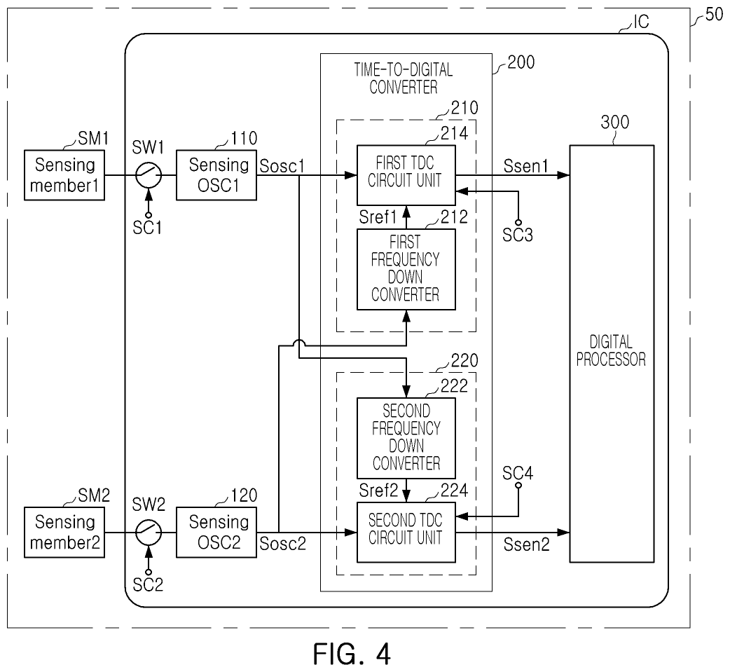

FIG. 4 is a view illustrating a time-digital converter.

Referring to FIG. 4, the first time-to-digital converter 210 may include a first frequency down converter 212 and a first TDC circuit unit 214.

The first frequency down converter 212 may lower the frequency of the second oscillation signal Sosc2, when the first switch SW1 is in an on-state, to generate the first reference signal Sref1.

The first TDC circuit unit 214 may be synchronized with an operation of the first switch SW1 according to the third control signal SC3. The first TDC circuit unit 214 may count the first oscillation signal Sosc1 using the first reference signal Sref1, when the first switch SW1 is in an on-state, to generate the first sensing signal Ssen1.

The second time-to-digital converter 220 may include a second frequency down converter 222 and a second TDC circuit unit 224.

The second frequency down converter 222 may lower the frequency of the first oscillation signal Sosc1 to generate the second reference signal Sref2.

The second TDC circuit unit 224 may be synchronized with an operation of the second switch SW2 according to the fourth control signal SC4. The second TDC circuit unit 224 may count the second oscillation signal Sosc2 using the second reference signal Sref2, when the second switch SW2 is in an on-state, to generate the second sensing signal Ssen2.

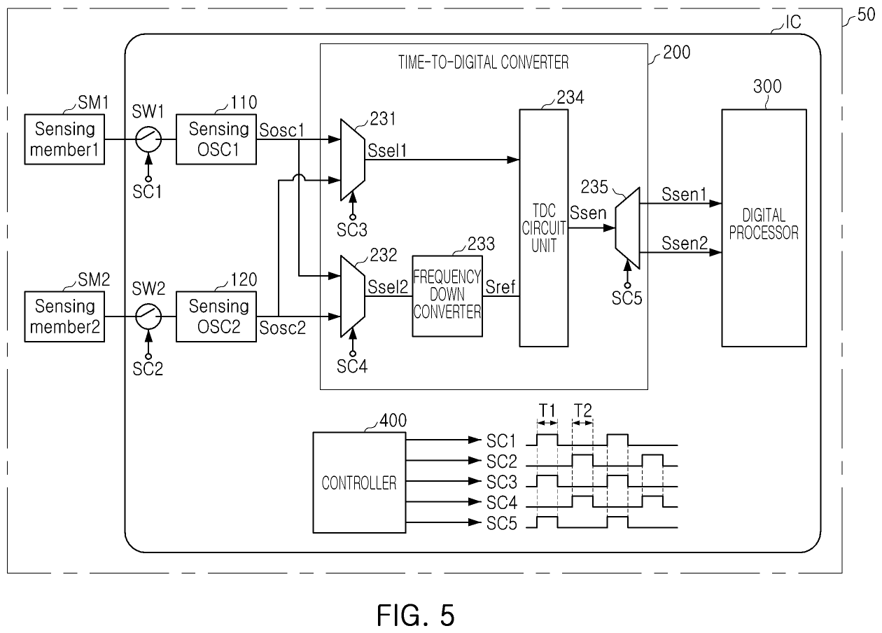

FIG. 5 is another view illustrating a time-digital converter.

Referring to FIG. 5, a time-to-digital converter 200 may include a first multiplexer 231, a second multiplexer 232, a frequency down converter 233, a TDC circuit 234, and a demultiplexer 235.

The first multiplexer 231 may select one of the first oscillation signal Sosc1 and the second oscillation signal Sosc2, according to a third control signal SC3, and may output a first selection signal Ssel1.

The second multiplexer 232 may select one of the first oscillation signal Sosc1 and the second oscillation signal Sosc2, according to a fourth control signal SC4, and may output a second selection signal Ssel2.

The frequency down converter 233 may lower a frequency of the second selection signal Ssel2 from the second multiplexer 232 to output a reference signal Sref.

The TDC circuit unit 234 may count the first selection signal Ssel1 from the first multiplexer 231 using the reference signal Sref from the frequency down converter 233, to generate a sensing signal Ssen.

The demultiplexer 235 may be synchronized with an operation of the first multiplexer 231 according to a fifth control signal SC5, and may output the sensing signal from the TDC circuit unit 234 to one of a first output terminal or a second output terminal.

As illustrated in FIG. 5, the controller 400 may generate a first control signal SC1, a second control signal SC2, a third control signal SC3, a fourth control signal SC4, and a fifth control signal SC5.

As described with reference to FIG. 3, the first control signal SC1 may have a high level and a low level, periodically repeated, and may be a control signal having a high level at a first time T1, and the control signal SC1 may be output from the controller 400, and may be supplied to the first switch SW1.

As explained with reference to FIG. 3, the second control signal SC2 may be a control signal that has a high level at a second time T2 when the first control signal SC1 has a low level, and the second control signal SC2 may be output from the controller 400, and may be supplied to the second switch SW2.

The third control signal SC3 may be a control signal synchronized with a first time T1 of the first control signal SC1, and the third control signal SC3 may be output from the controller 400 to the first multiplexer 231.

For example, the first multiplexer 231 may select and output a first oscillation signal Sosc1 according to a third control signal SC3, which is a high level, when the first switch SW1 is in an on-state (the second switch SW2 is in an off-state). The first multiplexer 231 may select and output a second oscillation signal Sosc2 according to a third control signal SC3, a lower level when the second switch SW2 is in an on-state (the first switch SW1 is in an off-state).

The fourth control signal SC4 may be a control signal synchronized with a second time T2 of the second control signal SC2, and the fourth control signal SC4 may be output from the controller 400 to the second multiplexer 232.

For example, the second multiplexer 232 may select and output a second oscillation signal Sosc2 according to a fourth control signal SC4, which is a lower level, when the second switch SW2 is in an off-state (the first switch SW1 is in an on-state), and may select and output a first oscillation signal Sosc1 according to a fourth control signal SC4, which is a high level, when the second switch SW2 is in an on-state (the first switch SW1 is in an off-state).

The fifth control signal SC5 may be a control signal synchronized with the first control signal SC1, and the fifth control signal SC5 may be output from the controller 400 and may be supplied to the demultiplexer 235.

For example, the demultiplexer 235 may select and output a sensing signal Ssen output from the TDC circuit unit 234 according to a fifth control signal SC5, which is a high level through a first output terminal, when the first switch SW5 is in an on-state (the second control signal SW2 is in an off-state), and may select and output a sensing signal Ssen output from the TDC circuit unit 234 according to a fifth control signal SC5, which is a lower level through a second output terminal, when the second switch SW2 is in an on-state (the first switch SW1 is in an off-state).

In FIG. 5, in response to the first control signal SC1, the first switch SW1 may be in an on-state at a first time T1 to connect the first sensing member SM1 and the first sensing oscillator 110, and may be in an off-state at the second time T2 to disconnect the first sensing member SM1 and the first sensing oscillator 110.

In response to the second control signal SC2, the second switch SW2 may be in an on-state at a second time T2 to connect the second sensing member SM2 and the second sensing oscillator 120, and may be in an off-state at the first time T1 to disconnect the second sensing member SM2 and the second sensing oscillator 120.

In response to the third control signal SC3 having a first time T1, which is on a high level, and a second time T2, which is on a low level, the first multiplexer 231 may select the first oscillation signal SC1 at the first time T1 and may select the second oscillation signal SC2 at the second time T2.

In response to the fourth control signal SC4 with a first time T1 having a low level, and a second time T2 having a high level, the second multiplexer 232 may select the second oscillation signal SC2 at the second time T2, and may select the first oscillation signal SC1 at the first time T1.

For example, when the first multiplexer 231 selects a first oscillation signal Sosc1, the second multiplexer 232 may select a second oscillation signal Sosc2. In contrast, when the first multiplexer 231 selects the second oscillation signal Sosc2, the second multiplexer 232 may select the first oscillation signal Sosc1.

In response to the fifth control signal SC5 having a first time T1, which is on a high level, and a second time T2, which is on a low level, the demultiplexer 235 may output the sensing signal Ssen output from the TDC circuit unit 234 at the first time T1 according to the fifth control signal SC5, which is on a high level, through a first output terminal, and may output the sensing signal Ssen output from the TDC circuit unit 234 at the second time T2 according to the fifth control signal SC5, which is on a low level, through a second output terminal.

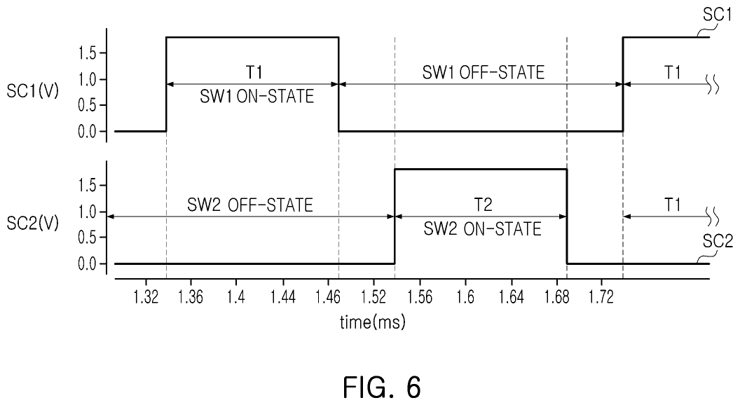

FIG. 6 illustrates a first control signal and a second control signal.

Referring to FIG. 6, a first control signal SC1 may be a control signal for controlling a first switch SW1 in an on-state or an off-state, may have a high level and a low level, periodically repeated, may have a high level at a first time T1 to control the first switch SW1 in an on-state, and may have a low level to control the first switch SW1 in an off-state.

The second control signal SC2 may be a control signal for controlling a second switch SW2 in an on-state or an off-state to operate complementary to the first switch SW1, may have a high level and a low level, periodically repeated, may have a high level at a second time T2 to control the second switch SW2 in an on-state when the first control signal SC1 has a low level, and may have a low level to control the second switch SW2 in an off-state.

In this case, to ensure a stable sensing operation, it may be set to have a dead time, which is a time period between a first time T1, which is a high level of the first control signal SC1, and a second time T2, which is a high level of the second control signal SC2.

Referring to FIGS. 3, 5, and 6, the third control signal SC3 and the fifth control signal SC5 may be synchronized with the first control signal SC1, and the fourth control signal SC4 may be synchronized with the second control signal SC2.

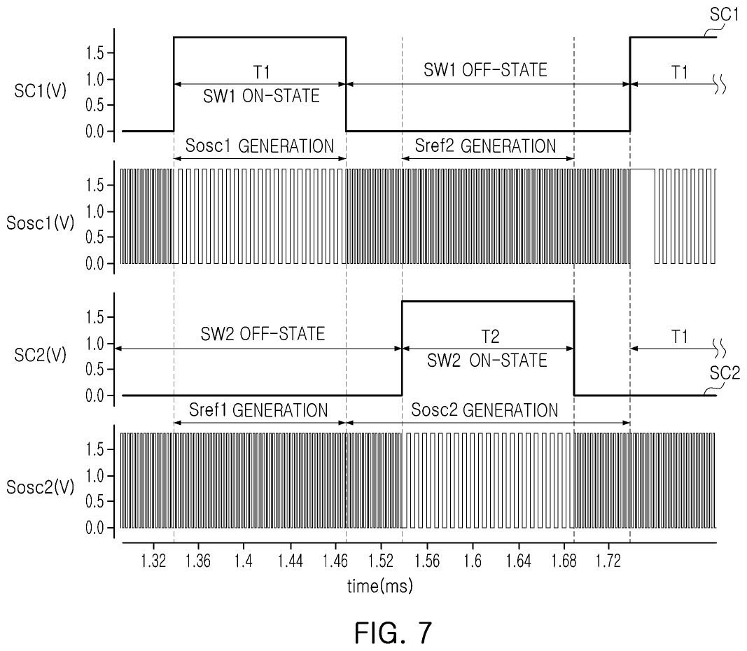

FIG. 7 illustrates first and second control signals, and first and second oscillation signals.

Referring to FIG. 7, as described above, a first control signal SC1 may have a high level at a first time T1 to control a first switch SW1 in an on-state, and may have a low level to control the first switch SW1 in an off-state.

In this case, when the first control signal SC1 is on a high level at the first time T1, a first sensing oscillator 110 may be connected to a first sensing member SM1, and may generate a first oscillation signal Sosc1 having a first frequency, changing according to the approach of a human body. In addition, when the first control signal SC1 is on a low level, the first sensing oscillator 110 may be disconnected from the first sensing member SM1, and may generate a first oscillation signal Sosc1 having a preset reference frequency regardless of the approach of the human body.

A second control signal SC2 may have a high level at a second time T2 to control a second switch SW1 in an on-state to operate complementary to the first switch SW1, and may have a low level to control the second switch SW2 in an off-state.

In this case, when the second control signal SC2 is on a high level at the second time T2, a second sensing oscillator 120 may be connected to a second sensing member SM2, and may generate a second oscillation signal Sosc2 having a second frequency, changing according to the approach of a human body. In addition, when the second control signal SC2 is on a low level, the second sensing oscillator 120 may be disconnected from the second sensing member SM2, and may generate a second oscillation signal Sosc2 having a preset reference frequency regardless of an approach of the human body.

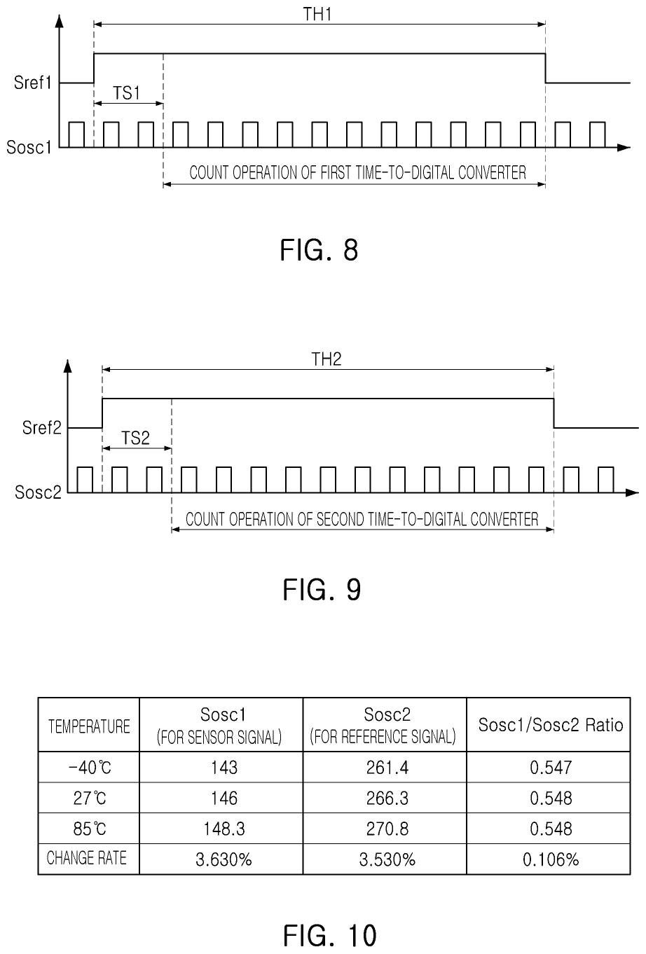

FIG. 8 is a view illustrating an operation of a first time-to-digital converter using a first oscillation signal and a first reference signal, and FIG. 9 is a view illustrating an operation of a second time-to-digital converter using a second oscillation signal and a second reference signal.

Referring to FIG. 8, when a first switch SW1 is in an on-state, a first sensing oscillator 110 may generate a first oscillation signal Sosc1, and a first time-to-digital converter (210 in FIGS. 3 and 4) may frequency down-convert a second oscillation signal Sosc2 to generate a first reference signal Sref1.

Therefore, the first reference signal Sref1 may have a frequency much lower than the frequency of the first oscillation signal Sosc1, e.g., a much longer cycle, and the first time-to-digital converter (210 in FIGS. 3 and 4) may count the number of pulses of the first oscillation signal Sosc1 during a high level section TH1 of the first reference signal Sref1.

The first time-digital converter (210 in FIGS. 3 and 4) may not perform a count operation during an initial time TS1, which is a frequency transition section and a section in which a frequency is not safe, in the high level section TH1 of the first reference signal Sref1 and, thereafter, may perform the count operation.

Referring to FIG. 9, when a second switch SW2 is in an on-state, a second sensing oscillator 120 may generate a second oscillation signal Sosc2, and a second time-to-digital converter (220 in FIGS. 3 and 4) may frequency down-convert a first oscillation signal Sosc1 to generate a second reference signal Sref2.

Therefore, the second reference signal Sref2 may have a frequency much lower than the frequency of the second oscillation signal Sosc2, e.g., a much longer cycle, and the second time-to-digital converter (220 in FIGS. 3 and 4) may count the number of pulses of the second oscillation signal Sosc2 during a high level section TH2 of the second reference signal Sref2.

The second time-digital converter (220 in FIGS. 3 and 4) may not perform a count operation during an initial time TS2, which is a frequency transition section and a section in which a frequency is not safe, in the high level section TH2 of the second reference signal Sref2 and, thereafter, may perform the count operation.

The initial time TS1 and initial time TS2 may exclude changes in frequency due to an unstable increase in capacitance at the beginning of sensing, and for a more stable count operation, a dead time during which the count operation is not performed. For example, the initial time TS1 and the initial time TS2 may be times corresponding to two or three clocks included in a corresponding oscillation signal, but are not limited thereto.

FIG. 10 is a view illustrating a change in count ratio, respectively, for a first oscillation signal (for sensor signal) of a first sensing oscillator and a second oscillation signal (for reference signal) of a second sensing oscillator according to a change in temperature.

Referring to FIG. 10, the count numbers of pulses of a first oscillation signal Sosc1 (for sensor signal) of a first sensing oscillator (110 in FIG. 2) according to a change in temperature of −40° C., 27° C., and 85° C. are 143, 146, 148.3, and a conversion rate of the count number is 3.630%.

In addition, the count numbers of pulses of a second oscillation signal Sosc2 (for reference signal) of a second sensing oscillator (120 in FIG. 2) according to a change in temperature of −40° C., 27° C., and 85° C. are 261.4, 266.3, and 270.8, and a conversion rate of the count number is 3.530%.

Therefore, ratios of the count numbers of pulses of the first oscillation signal Sosc1 (for sensor signal) and the count numbers of pulses of the second oscillation signal Sosc2 (for reference signal) of the second sensing oscillator (120 in FIG. 2) according to a change in temperature of 40° C., 27° C., and 85° C. are 0.547, 0.548, and 0.548, and a conversion rate thereof is 0.106%.

Therefore, according to the present disclosure, even when there is a change in temperature, it can be seen that the conversion rate of the count numbers is lowered to be about 0.1%. Therefore, an improvement of about 1/35 in terms of resolution may be achieved. For example, the resolution may be improved to have about 5.1 bit.

In the end, according to the present disclosure, there may be advantages that a method may be implemented without a change in an external algorithm or without an additional circuit and advantages that resolution may increase by more than 5 bits and improve temperature characteristics, as compared to the existing method.

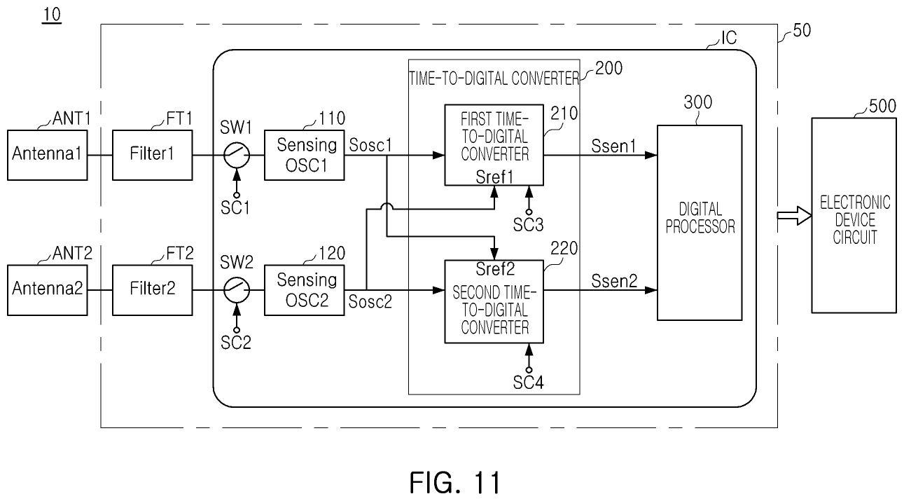

FIG. 11 is a view illustrating an application of a grip sensor according to the present disclosure to an electronic device.

Referring to FIG. 11, when a grip sensor 50 of the present disclosure is applied to an electronic device 10, a first switch SW1 of a grip sensor circuit IC of the present disclosure may be connected to a first antenna ANT1 through a filter FT1, and a second switch SW2 of the grip sensor circuit IC may be connected to a second antenna ANT2 through a second filter FT2.

According to an embodiment of the present disclosure, among two sensor circuits designed to have the same temperature characteristics, an operation in which one thereof generates a sensing signal, and an operation in which the other thereof generates a reference signal may be performed alternately to provide an effect of removing offset drift due to a temperature.

An aspect of the present disclosure is to provide a grip sensor and an electronic device in which, among two sensor circuits designed to have the same temperature characteristics, an operation in which one thereof generates a sensing signal, and an operation in which the other thereof generates a reference signal are performed alternately. Thus, the grip sensor may adequately distinguish between a change due to temperature and a change due to actual grip.

The controller 400 described herein and disclosed herein described with respect to FIGS. 1-11 is implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

While specific examples have been shown and described above, it will be apparent after an understanding of this disclosure that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A grip sensor comprising:
a first sensing member and a second sensing member, disposed on different positions in a case of an electronic device to sense proximity of a human body;
a first sensing oscillator configured to generate a first oscillation signal having a first frequency, varying based on the proximity of the human body, when connected to the first sensing member, and having a preset reference frequency, when not connected to the first sensing member;
a second sensing oscillator configured to generate a second oscillation signal having a second frequency, varying based on the proximity of the human body, when connected to the second sensing member, and having the preset reference frequency, when not connected to the second sensing member;
a first switch configured connect or disconnect from the first sensing member and the first sensing oscillator;
a second switch configured to operate complementarily to the first switch, and connect or disconnect from the second sensing member and the second sensing oscillator;
a time-to-digital converter configured to set the second oscillation signal as a first reference signal, when the first switch is in an on-state, and generate a first sensing signal using the first oscillation signal and the first reference signal; and
a digital processor configured to sense the proximity of the human body to the first sensing member, using the first sensing signal.

2. The grip sensor of claim 1, wherein the time-to-digital converter is configured to set the first oscillation signal as a second reference signal, when the second switch is in an on-state, and generate a second sensing signal using the second reference signal and the second oscillation signal, and
the digital processor is configured to sense the proximity of the human body to the second sensing member, using the second sensing signal.

3. The grip sensor of claim 2, further comprising a controller is configured to generate a first control signal, a second control signal, a third control signal, and a fourth control signal, wherein the time-to-digital converter comprises:
a first time-to-digital converter synchronized with an operation of the first switch according to the third control signal, generating a first reference signal using the second oscillation signal, when the first switch is in an on-state, and generating a first sensing signal using the first oscillation signal and the first reference signal; and
a second time-to-digital converter synchronized with an operation of the second switch according to the fourth control signal, generating a second reference signal using the first oscillation signal, when the second switch is in an on-state, and generating a second sensing signal using the second reference signal and the second oscillation signal.

4. The grip sensor of claim 3,
wherein the first control signal has a high level signal and a low level signal, periodically repeated, and become a high level signal at a first time to and be output the first switch,
the second control signal has a high level signal at a second time when the first control signal has a low level signal, and is output to the second switch,
the third control signal has an enable level signal synchronized at a first time of the first control signal and is output to a first time-digital converter, and
the fourth control signal has an enable level signal synchronized at a second time of the second control signal and is output to a second time-digital converter.

5. The grip sensor of claim 4, wherein, in response to the first control signal, the first switch is in an on-state at a first time to connect the first sensing member and the first sensing oscillator, and is in an off-state at the second time to disconnect the first sensing member and the first sensing oscillator,
in response to the second control signal, the second switch is in an on-state at a second time to connect the second sensing member and the second sensing oscillator, and is in an off-state at the first time to disconnect the second sensing member and the second sensing oscillator,
in response to the third control signal having an enable level signal at a first time and a disable level signal at a second time, the first time-to-digital converter performs an operation at the first time and stops an operation at the second time, and
in response to the fourth control signal having a disable level signal at a first time and an enable level signal at a second time, the second time-to-digital converter performs an operation at the second time and stops an operation at the first time.

6. The grip sensor of claim 4, wherein the first time-to-digital converter comprises:
a first frequency down converter configured to lower a frequency of the second oscillation signal, when the first switch is in an on-state, to generate the first reference signal; and
a first time-to-digital converter (TDC) circuit unit synchronized with an operation of the first switch according to the third control signal, and configured to count the first oscillation signal using the first reference signal, when the first switch is in an on-state, to generate the first sensing signal, and
the second time-to-digital converter comprises:
a second frequency down converter configured to lower a frequency of the first oscillation signal to generate the second reference signal; and
a second TDC circuit unit synchronized with an operation of the second switch according to the fourth control signal, and configured to count the second oscillation signal using the second reference signal, when the second switch is in an on-state, to generate the second sensing signal.

7. The grip sensor of claim 2, wherein the time-to-digital converter comprises:
a first multiplexer configured to select one of the first oscillation signal or the second oscillation signal according to a third control signal, and output a first selection signal;
a second multiplexer configured to select the other one of the first oscillation signal or the second oscillation signal according to a fourth control signal, and output a second selection signal;
a frequency down converter configured to lower a frequency of the second selection signal from the second multiplexer to output a reference signal;
a TDC circuit unit configured to count the first selection signal from the first multiplexer using the reference signal from the frequency down converter, to generate a sensing signal; and
a demultiplexer synchronized with an operation of the first multiplexer according to a fifth control signal, and configured to output the sensing signal from the TDC circuit unit to one of a first output terminal or a second output terminal.

8. The grip sensor of claim 7, further comprising a controller configured to have a high level signal and a low level signal, periodically repeated, generating and outputting a first control signal having a high level signal at a first time to the first switch, generating and outputting a second control signal having a high level signal at a second time to the second switch when the first control signal has a low level signal, generating and outputting a third control signal synchronized at a first time of the first control signal to the first multiplexer, generating and outputting a fourth control signal synchronized at a second time of the second control signal to the second multiplexer, and generating and outputting a fifth control signal synchronized with the first control signal to the demultiplexer.

9. The grip sensor of claim 8, wherein, in response to the first control signal, the first switch is in an on-state at a first time to connect the first sensing member and the first sensing oscillator, and is in an off-state at the second time to disconnect the first sensing member and the first sensing oscillator,
in response to the second control signal, the second switch is in an on-state at a second time to connect the second sensing member and the second sensing oscillator, and is in an off-state at the first time to disconnect the second sensing member and the second sensing oscillator,
in response to the third control signal having a first time, a high level signal, and a second time, a low level signal, the first multiplexer is configured to select the first oscillation signal at the first time and select the second oscillation signal at the second time,
in response to the fourth control signal having a first time, a disable level signal, and a second time, an enable level signal, the second multiplexer is configured to select the second oscillation signal at the second time and select the first oscillation signal at the first time, and
in response to the fifth control signal having a first time, a high level signal, and a second time, a low level signal, the demultiplexer outputs the sensing signal output from the TDC circuit unit at the first time according to the fifth control signal, a high level signal, through a first output terminal, and outputs the sensing signal output from the TDC circuit unit at the second time according to the fifth control signal, a low level signal, through a second output terminal.

10. An electronic device comprising:
a case of the electronic device;
a grip sensor disposed in the case to sense proximity of a human body; and
an electronic device circuit configured to receive a detection signal from the grip sensor,
wherein the grip sensor includes:
a first sensing member and a second sensing member, disposed on different positions in the case to sense the proximity of the human body;
a first sensing oscillator configured to generate a first oscillation signal having a first frequency, varying based on the proximity of the human body, when connected to the first sensing member, and having a preset reference frequency, when not connected to the first sensing member;
a second sensing oscillator configured to generate a second oscillation signal having a second frequency, varying based on the proximity of the human body, when connected to the second sensing member, and having the reference frequency, when not connected to the second sensing member;
a first switch configured to connect or disconnect from the first sensing member and the first sensing oscillator;
a second switch configured to operate complementarily to the first switch, and connect or disconnect from the second sensing member and the second sensing oscillator;
a time-to-digital converter configured to set the second oscillation signal as a first reference signal, when the first switch is in an on-state, and generate a first sensing signal using the first oscillation signal and the first reference signal; and
a digital processor configured to sense the proximity of the human body to the first sensing member, using the first sensing signal.

11. The electronic device of claim 10, wherein the time-to-digital converter is configured to set the first oscillation signal as a second reference signal, when the second switch is in an on-state, and generate a second sensing signal using the second reference signal and the second oscillation signal, and
the digital processor is configured to sense the proximity of the human body to the second sensing member, using the second sensing signal.

12. The electronic device of claim 11, further comprising a controller configured to generate a first control signal, a second control signal, a third control signal, and a fourth control signal,
wherein the time-to-digital converter comprises:
a first time-to-digital converter synchronized with an operation of the first switch according to the third control signal, generating a first reference signal using the second oscillation signal, when the first switch is in an on-state, and generating a first sensing signal using the first oscillation signal and the first reference signal; and
a second time-to-digital converter synchronized with an operation of the second switch according to the fourth control signal, generating a second reference signal using the first oscillation signal, when the second switch is in an on-state, and generating a second sensing signal using the second reference signal and the second oscillation signal.

13. The electronic device of claim 12,
wherein, the first control signal has a high level signal and a low level signal, periodically repeated, and become a high level signal at a first time to and be output the first switch SW1,
the second control signal has a high level signal at a second time when the first control signal has a low level signal, and is output to the second switch,
the third control signal has an enable level signal synchronized at a first time of the first control signal and is output to a first time-digital converter, and
the fourth control signal has an enable level signal synchronized at a second time of the second control signal and is output to a second time-digital converter.

14. The electronic device of claim 13, wherein, in response to the first control signal, the first switch is in an on-state at a first time to connect the first sensing member and the first sensing oscillator, and is in an off-state at the second time to disconnect the first sensing member and the first sensing oscillator,
in response to the second control signal, the second switch is in an on-state at a second time to connect the second sensing member and the second sensing oscillator, and is in an off-state at the first time to disconnect the second sensing member and the second sensing oscillator,
in response to the third control signal having an enable level signal at a first time and a disable level signal at a second time, the first time-to-digital converter performs an operation at the first time and stops an operation at the second time, and
in response to the fourth control signal having a disable level signal at a first time and an enable level signal at a second time, the second time-to-digital converter performs an operation at the second time and stops an operation at the first time.

15. The electronic device of claim 13, wherein the first time-to-digital converter comprises:
a first frequency down converter configured to lower a frequency of the second oscillation signal to generate the first reference signal; and
a first time-to-digital converter (TDC) circuit unit synchronized with an operation of the first switch according to the third control signal, and configured to count the first oscillation signal using the first reference signal, when the first switch is in an on-state, to generate the first sensing signal, and
the second time-to-digital converter comprises:
a second frequency down converter configured to lower a frequency of the first oscillation signal to generate the second reference signal; and
a second TDC circuit unit synchronized with an operation of the second switch according to the fourth control signal, and configured to count the second oscillation signal using the second reference signal, when the second switch is in an on-state, to generate the second sensing signal.

16. The electronic device of claim 11, wherein the time-to-digital converter comprises:
a first multiplexer configured to select one of the first oscillation signal or the second oscillation signal according to a third control signal, and output a first selection signal;
a second multiplexer configured to select the other one of the first oscillation signal or the second oscillation signal according to a fourth control signal, and output a second selection signal;
a frequency down converter configured to lower a frequency of the second selection signal from the second multiplexer to output a reference signal;
a TDC circuit unit configured to count the first selection signal from the first multiplexer using the reference signal from the frequency down converter, to generate a sensing signal; and
a demultiplexer synchronized with an operation of the first multiplexer according to a fifth control signal, and configured to output the sensing signal from the TDC circuit unit to one of a first output terminal or a second output terminal.

17. The electronic device of claim 16, further comprising a controller configured to have a high level signal and a low level signal, periodically repeated, generating and outputting a first control signal having a high level signal at a first time to the first switch, generating and outputting a second control signal having a high level signal at a second time to the second switch when the first control signal has a low level signal, generating and outputting a third control signal synchronized at a first time of the first control signal to the first multiplexer, generating and outputting a fourth control signal synchronized at a second time of the second control signal to the second multiplexer, and generating and outputting a fifth control signal synchronized with the first control signal to the demultiplexer.

18. The electronic device of claim 17, wherein, in response to the first control signal, the first switch is in an on-state at a first time to connect the first sensing member and the first sensing oscillator, and is in an off-state at the second time to disconnect the first sensing member and the first sensing oscillator,
in response to the second control signal, the second switch is in an on-state at a second time to connect the second sensing member and the second sensing oscillator, and is in an off-state at the first time to disconnect the second sensing member and the second sensing oscillator,
in response to the third control signal having a first time, a high level signal, and a second time, a low level signal, the first multiplexer is configured to select the first oscillation signal at the first time and select the second oscillation signal at the second time,
in response to the fourth control signal having a first time, a disable level signal, and a second time, an enable level signal, the second multiplexer is configured to select the second oscillation signal at the second time and select the first oscillation signal at the first time, and
in response to the fifth control signal having a first time, a high level signal, and a second time, a low level signal, the demultiplexer outputs the sensing signal output from the TDC circuit unit at the first time according to the fifth control signal, a high level signal, through a first output terminal, and outputs the sensing signal output from the TDC circuit unit at the second time according to the fifth control signal, a low level signal, through a second output terminal.
